(19) United States
(12) Patent Application Publication
(10) Pub. No.: US 2025/0264804 A1
(43) Pub. Date: Aug. 21, 2025

(54) EXPOSURE SYSTEM AND METHOD OF MANUFACTURING ELECTRONIC DEVICE

(71) Applicant: Gigaphoton Inc., Tochigi (JP)

(72) Inventor: Koichi FUJII, Oyama-shi (JP)

(73) Assignee: Gigaphoton Inc., Tochigi (JP)

(21) Appl. No.: 19/199,798

(22) Filed: May 6, 2025

Related U.S. Application Data
(63) Continuation of application No. PCT/JP2022/046927, filed on Dec. 20, 2022.

(51) Int. Cl. G03F 7/20

(52) U.S. Cl. CPC G03F 7/2008; G03F 7/2006

(57) ABSTRACT

An exposure system includes an illumination optical system configured to illuminate a photomask with a pulse laser beam including a plurality of center wavelengths, and a projection optical system configured to illuminate a photosensitive substrate with the pulse laser beam that has passed through the photomask and to project an image of the photomask. A position of a first pupil that is a pupil of the illumination optical system is shifted from a reference position in a conjugate relationship with a second pupil that is a pupil of the projection optical system in a direction of reducing, by a magnification telecentric error, deviation of an imaging position due to lateral chromatic aberration on the photosensitive substrate.

### CROSS-REFERENCE TO RELATED APPLICATIONS

The present application is a continuation application of International Application No. PCT/JP2022/046927, filed on Dec. 20, 2022, the entire contents of which are hereby incorporated by reference.

### BACKGROUND

### 1. Technical Field

The present disclosure relates to an exposure system and a method of manufacturing an electronic device.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. A gas laser apparatus with a narrowed spectral linewidth is referred to as a line narrowing gas laser apparatus.

### LIST OF DOCUMENT

### Patent Document

Patent Document 1: International Publication No. WO2021/110343

### SUMMARY

In one aspect of the present disclosure, an exposure system includes an illumination optical system and a projection optical system. The illumination optical system is configured to illuminate a photomask with a pulse laser beam including a plurality of center wavelengths. The projection optical system is configured to illuminate a photosensitive substrate with the pulse laser beam that has passed through the photomask and to project an image of the photomask. A position of a first pupil that is a pupil of the illumination optical system is shifted from a reference position in a conjugate relationship with a second pupil that is a pupil of the projection optical system in a direction of reducing, by a magnification telecentric error, deviation of an imaging position due to lateral chromatic aberration on the photosensitive substrate.

In one aspect of the present disclosure, a method of manufacturing an electronic device includes exposing, with an exposure system, a photosensitive substrate to a pulse laser beam to manufacture the electronic device. The exposure system includes an illumination optical system configured to illuminate a photomask with the pulse laser beam including a plurality of center wavelengths, and a projection optical system configured to illuminate the photosensitive substrate with the pulse laser beam that has passed through the photomask and to project an image of the photomask, a position of a first pupil that is a pupil of the illumination optical system being shifted from a reference position in a conjugate relationship with a second pupil that is a pupil of the projection optical system in a direction of reducing, by a magnification telecentric error, deviation of an imaging position due to lateral chromatic aberration on the photosensitive substrate.

### BRIEF DESCRIPTION OF THE DRAWINGS

Some embodiments of the present disclosure will be described below, by way of example only, with reference to the accompanying drawings.

FIG. 1 schematically illustrates a configuration of an exposure system in a comparative example.

FIG. 2 schematically illustrates a configuration of a laser apparatus.

FIG. 3 is a graph illustrating a periodic wavelength change.

FIG. 4 illustrates an integrated spectrum of a pulse laser beam including a plurality of center wavelengths.

FIG. 5 illustrates a photosensitive substrate exposed by an exposure apparatus.

FIG. 6 is a diagram explaining how a position of a scan field of a photosensitive substrate changes with respect to a position of a beam cross section of a pulse laser beam.

FIG. 7 is a diagram explaining how the position of the scan field of the photosensitive substrate changes with respect to the position of the beam cross section of the pulse laser beam.

FIG. 8 is a diagram explaining how the position of the scan field of the photosensitive substrate changes with respect to the position of the beam cross section of the pulse laser beam.

FIG. 9 is a schematic diagram of a projection optical system included in the exposure apparatus.

FIG. 10 illustrates how an image formed on a photosensitive substrate is deformed by the projection optical system illustrated in FIG. 9.

FIG. 11 is a schematic diagram of an optical system including a part of an illumination optical system and a both-side telecentric projection optical system.

FIG. 12 illustrates a change in a main light beam when a pupil of the illumination optical system is shifted in a direction of an optical axis in the optical system illustrated in FIG. 11.

FIG. 13 is a diagram explaining how an image formed on a photosensitive substrate is changed by the optical system illustrated in FIG. 12.

FIG. 14 is a diagram explaining how an image formed on the photosensitive substrate is changed by the optical system illustrated in FIG. 12.

FIG. 15 is a diagram explaining how an image formed on the photosensitive substrate is changed by the optical system illustrated in FIG. 12.

FIG. 16 illustrates a change in the main light beam when the pupil of the illumination optical system is shifted in a direction opposite to that in FIG. 12 in the optical system illustrated in FIG. 11.

FIG. 17 is a diagram explaining how an image formed on the photosensitive substrate is changed by the optical system illustrated in FIG. 16.

FIG. 18 is a diagram explaining how an image formed on the photosensitive substrate is changed by the optical system illustrated in FIG. 16.

FIG. 19 is a diagram explaining how an image formed on the photosensitive substrate is changed by the optical system illustrated in FIG. 16.

FIG. 20 is a schematic diagram illustrating a part of a marginal light beam of a pulse laser beam incident on a workpiece table when longitudinal chromatic aberration and lateral chromatic aberration occur.

FIG. 21 schematically illustrates an imaging region of light of each wavelength of the pulse laser beam illustrated in FIG. 20.

FIG. 22 is a sectional view illustrating a resist profile when the photosensitive substrate exposed to the pulse laser beam illustrated in FIG. 20 and FIG. 21 is developed.

FIG. 23 illustrates deviation of an image on the photosensitive substrate scan-exposed to the pulse laser beam illustrated in FIG. 20 and FIG. 21.

FIG. 24 is a schematic diagram illustrating a part of the main light beam of the pulse laser beam incident on the workpiece table when a magnification telecentric error occurs.

FIG. 25 schematically illustrates an imaging region of light of each wavelength of the pulse laser beam illustrated in FIG. 24.

FIG. 26 schematically illustrates an imaging region of light of each wavelength when the lateral chromatic aberration is taken into consideration in the pulse laser beam illustrated in FIG. 24.

FIG. 27 is a schematic diagram illustrating a part of the main light beam of the pulse laser beam incident on the workpiece table when the magnification telecentric error occurs in a direction opposite to that in FIG. 24.

FIG. 28 schematically illustrates an imaging region of light of each wavelength of the pulse laser beam illustrated in FIG. 27.

FIG. 29 schematically illustrates an imaging region of light of each wavelength when the lateral chromatic aberration is taken into consideration in the pulse laser beam illustrated in FIG. 27.

FIG. 30 schematically illustrates a configuration of an exposure system according to a first embodiment.

FIG. 31 conceptually illustrates a first example of an illumination optical system capable of moving a position of a pupil.

FIG. 32 conceptually illustrates a second example of the illumination optical system capable of moving the position of the pupil.

FIG. 33 conceptually illustrates a third example of the illumination optical system capable of moving the position of the pupil.

FIG. 34 is a flowchart illustrating processing of correcting magnification distortion in the first embodiment.

FIG. 35 schematically illustrates a configuration of an exposure system according to a second embodiment.

FIG. 36 is a flowchart illustrating processing of creating a correction table in the second embodiment.

FIG. 37 illustrates an example of the correction table stored in a nonvolatile memory.

FIG. 38 is a flowchart illustrating processing of correcting magnification distortion in the second embodiment.

FIG. 39 schematically illustrates a configuration of an exposure system according to a third embodiment.

FIG. 40 is a flowchart illustrating processing of correcting magnification distortion in the third embodiment.

### DESCRIPTION OF EMBODIMENTS

### <Contents>

1. Comparative Example
   1.1 Exposure Apparatus 200
      1.1.1 Configuration
      1.1.2 Operation
   1.2 Laser Apparatus 100
      1.2.1 Configuration
      1.2.2 Operation
   1.3 Line Narrowing Module 14
      1.3.1 Configuration
      1.3.2 Operation
   1.4 Periodic Wavelength Change and Integrated Spectrum
   1.5 Scan Exposure
   1.6 Magnification Distortion
   1.7 Chromatic Aberration
   1.8 Magnification Chromatic Aberration
   1.9 Magnification Telecentric Error
   1.10 Problem of Comparative Example
2. Exposure System in which Position of Pupil IP of Illumination Optical System 201 is Shifted
   2.1 Principle
   2.2 Configuration
   2.3 Operation (Correction of Magnification Distortion)
   2.4 Effect
3. Exposure System that Determines Position of Pupil IP of Illumination Optical System 201 Based on Spectral Parameter
   3.1 Configuration
   3.2 Operation
      3.2.1 Creation of Correction Table
      3.2.2 Correction of Magnification Distortion
   3.3 Effect
4. Exposure System Including Measurement Unit 303b Separate from Exposure Apparatus 200
   4.1 Configuration
   4.2 Operation (Correction of Magnification Distortion)
   4.3 Effect
5. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

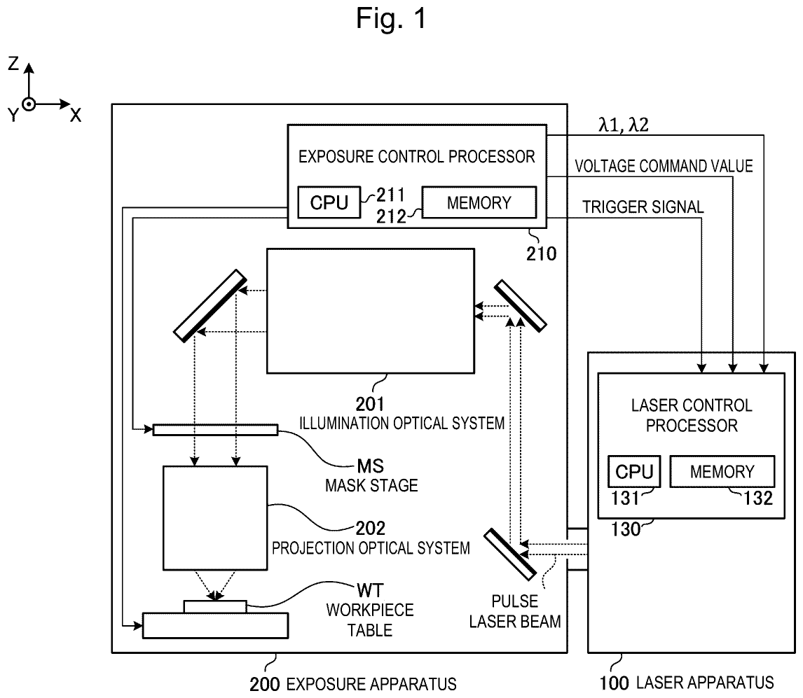

FIG. 1 schematically illustrates a configuration of an exposure system in a comparative example. The comparative example of the present disclosure is an example recognized by the applicant as known only by the applicant, and is not a publicly known example admitted by the applicant. FIG. 1 illustrates an X axis, a Y axis, and a Z axis perpendicular to each other. The exposure system includes a laser apparatus 100 and an exposure apparatus 200. In FIG. 1, the laser apparatus 100 is illustrated in a simplified manner.

The laser apparatus 100 includes a laser control processor 130. The laser control processor 130 is a processing device including a memory 132 in which a control program is stored, and a CPU (central processing unit) 131 which executes the control program. The laser control processor 130 is specially configured or programmed to execute various kinds of processing included in the present disclosure. The laser apparatus 100 is configured to output a pulse laser beam toward the exposure apparatus 200.

### 1.1 Exposure Apparatus 200

### 1.1.1 Configuration

As illustrated in FIG. 1, the exposure apparatus 200 includes an illumination optical system 201, a projection optical system 202, and an exposure control processor 210. The illumination optical system 201 illuminates an unillustrated photomask disposed on a mask stage MS with the pulse laser beam incoming from the laser apparatus 100.

The projection optical system 202 illuminates an unillustrated workpiece placed on a workpiece table WT with the pulse laser beam that has passed through the photomask, and projects an image of the photomask. The workpiece is a photosensitive substrate such as a semiconductor wafer on which a resist film is applied.

The exposure control processor 210 is a processing device including a memory 212 in which a control program is stored and a CPU 211 which executes the control program. The exposure control processor 210 corresponds to a processor in the present disclosure. The exposure control processor 210 is specially configured or programmed to execute various kinds of processing included in the present disclosure. The exposure control processor 210 coordinates control of the exposure apparatus 200, and transmits and receives various kinds of parameters and various kinds of signals to and from the laser control processor 130.

### 1.1.2 Operation

The exposure control processor 210 transmits various kinds of parameters including a target short wavelength λ1, a target long wavelength λ2, and a voltage command value, and a trigger signal to the laser control processor 130. The laser control processor 130 controls the laser apparatus 100 according to these parameters and signal. The target short wavelength λ1 corresponds to a first wavelength in the present disclosure, and the target long wavelength λ2 corresponds to a second wavelength in the present disclosure.

The exposure control processor 210 synchronously translates the mask stage MS and the workpiece table WT in opposite directions. Thus, the workpiece is exposed to the pulse laser beam reflecting a mask pattern of the photomask.

The mask pattern is transferred to the photosensitive substrate by photolithography as described above. Thereafter, an electronic device can be manufactured through a plurality of processes.

### 1.2 Laser Apparatus 100

### 1.2.1 Configuration

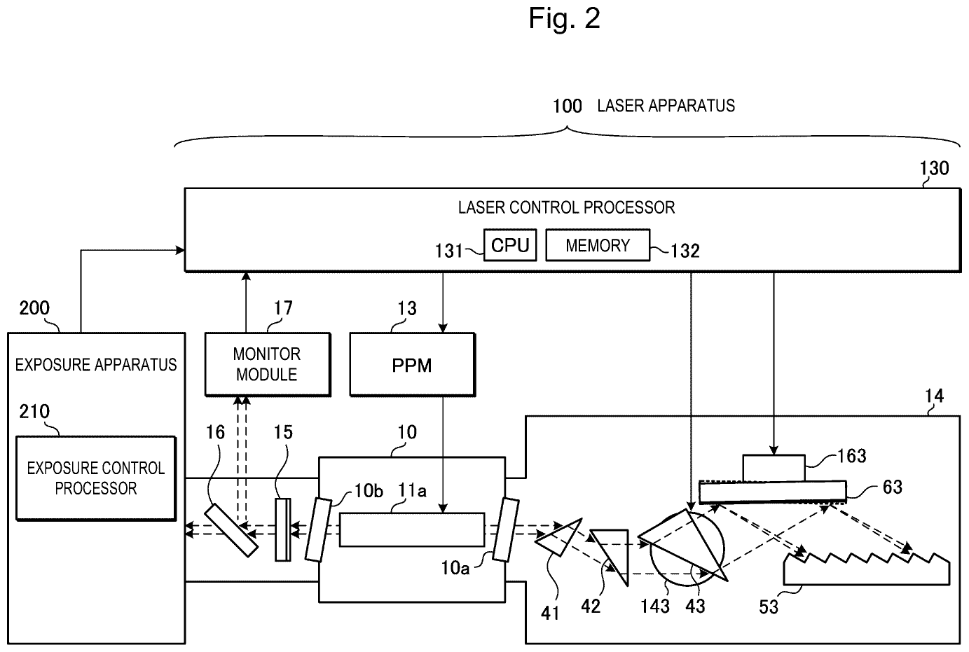

FIG. 2 schematically illustrates a configuration of the laser apparatus 100. In FIG. 2, the exposure apparatus 200 is illustrated in a simplified manner. In addition to the laser control processor 130, the laser apparatus 100 includes a laser chamber 10, a pulse power module (PPM) 13, a line narrowing module 14, an output coupling mirror 15, and a monitor module 17. The line narrowing module 14 and the output coupling mirror 15 form an optical resonator.

The laser chamber 10 is disposed in an optical path of the optical resonator. The laser chamber 10 is provided with windows 10a and 10b. The laser chamber 10 includes a discharge electrode 11a and an unillustrated discharge electrode paired with the discharge electrode 11a inside the laser chamber 10. The laser chamber 10 is filled with a laser gas containing, for example, an argon gas or a krypton gas as a rare gas, a fluorine gas as a halogen gas, and a neon gas as a buffer gas, or the like.

The pulse power module 13 includes an unillustrated switch, and is connected to an unillustrated charger.

The line narrowing module 14 includes prisms 41 to 43, a grating 53, and a mirror 63. Details of the line narrowing module 14 will be described later.

The output coupling mirror 15 is formed of a partial reflective mirror. A beam splitter 16 that transmits a part of the pulse laser beam with a high transmittance and reflects the other part is disposed in an optical path of the pulse laser beam passing through the output coupling mirror 15. The monitor module 17 is disposed in an optical path of the pulse laser beam reflected by the beam splitter 16.

### 1.2.2 Operation

The laser control processor 130 acquires various kinds of parameters including the target short wavelength λ1, the target long wavelength λ2, and the voltage command value from the exposure control processor 210. The laser control processor 130 transmits a control signal to the line narrowing module 14 based on the target short wavelength λ1 and the target long wavelength λ2.

The laser control processor 130 receives the trigger signal from the exposure control processor 210. The laser control processor 130 transmits an oscillation trigger signal based on the trigger signal to the pulse power module 13. The switch included in the pulse power module 13 is turned to an ON state when the oscillation trigger signal is received from the laser control processor 130. When the switch is turned to the ON state, the pulse power module 13 generates a pulsed high voltage from electric energy charged in the charger, and applies the high voltage to the discharge electrode 11a.

When the high voltage is applied to the discharge electrode 11a, discharge occurs in a discharge space between the discharge electrode 11a and the unillustrated discharge electrode. By energy of the discharge, the laser gas in the laser chamber 10 is excited and shifts to a high energy level. When the excited laser gas then shifts to a low energy level, light having a wavelength corresponding to the energy level difference is discharged.

The light generated in the laser chamber 10 is output to an outside of the laser chamber 10 through the windows 10a and 10b. The light passing through the window 10a enters the line narrowing module 14. Of the light that has entered the line narrowing module 14, light near a desired wavelength is turned back by the line narrowing module 14 and returned to the laser chamber 10.

The output coupling mirror 15 transmits a part of the light passing through the window 10b so that the part of the light exits the output coupling mirror 15, and reflects the other part back into the laser chamber 10.

In this way, the light output from the laser chamber 10 reciprocates between the line narrowing module 14 and the output coupling mirror 15. The light is amplified every time it passes through the discharge space in the laser chamber 10. Further, the light is narrowed every time it is turned back by the line narrowing module 14, and becomes light having a steep wavelength distribution with a part of a range of a selected wavelength by means of the line narrowing module 14 as a center wavelength. The light laser-oscillated and narrowed in this way is output as a pulse laser beam from the output coupling mirror 15.

The monitor module 17 measures the center wavelength of the pulse laser beam and transmits a measured wavelength to the laser control processor 130. The laser control processor 130 feedback-controls the line narrowing module 14 based on the measured wavelength. The pulse laser beam transmitted through the beam splitter 16 enters the exposure apparatus 200.

### 1.3 Line Narrowing Module 14

### 1.3.1 Configuration

The prisms 41 to 43 are disposed in an optical path of a light beam passing through the window 10a in an order from the smallest of the reference numerals of these prisms. The prism 43 is rotatable about an axis perpendicular to a plane of FIG. 2 by a rotating stage 143.

The mirror 63 is disposed in an optical path of the light beam transmitted through the prisms 41 to 43. The mirror 63 is rotatable about an axis perpendicular to the plane of FIG. 2 by a rotating stage 163. The grating 53 is disposed in an optical path of the light beam reflected by the mirror 63.

### 1.3.2 Operation

Each of the prisms 41 to 43 expands a beam width of the light beam passing through the window 10a in a plane parallel to the plane of FIG. 2. The light beam transmitted through the prisms 41 to 43 is reflected by the mirror 63 and incident on the grating 53.

The light beam incident on the grating 53 is reflected by a plurality of grooves of the grating 53 and is diffracted in a direction corresponding to the wavelength of the light. The grating 53 is disposed in Littrow arrangement such that an incident angle of the light beam from the mirror 63 onto the grating 53 coincides with a diffracting angle of diffracted light of a desired wavelength.

The mirror 63 and the prisms 41 to 43 reduce the beam width of the light beam returned from the grating 53 in the plane parallel to the plane of FIG. 2, and return the light beam to the inside of the laser chamber 10 through the window 10a.

The laser control processor 130 controls the rotating stages 143 and 163 via an unillustrated driver. In accordance with rotation angles of the rotating stages 143 and 163, the incident angle of the light beam on the grating 53 changes, and the wavelength selected by the line narrowing module 14 changes.

The laser control processor 130 controls the rotating stage 163 such that a posture of the mirror 63 periodically changes for each of a plurality of pulses, based on the target short wavelength λ1 and the target long wavelength λ2 received from the exposure control processor 210. Thus, the center wavelength of the pulse laser beam periodically changes between the target short wavelength λ1 and the target long wavelength λ2 for each of the pulses. In this way, the laser apparatus 100 outputs the pulse laser beam including a plurality of center wavelengths.

A focal length in the exposure apparatus 200 depends on the wavelength of the pulse laser beam. Since the pulse laser beam that is laser-oscillated at the multiple wavelengths and enters the exposure apparatus 200 can be imaged at a plurality of different positions in a direction of an optical path axis of the pulse laser beam, a focal depth can be substantially increased. For example, even when a resist film having a large thickness is exposed, imaging performance in a thickness direction of the resist film can be maintained. Alternatively, a resist profile indicating a cross-sectional shape of the developed resist film can be adjusted.

### 1.4 Periodic Wavelength Change and Integrated Spectrum

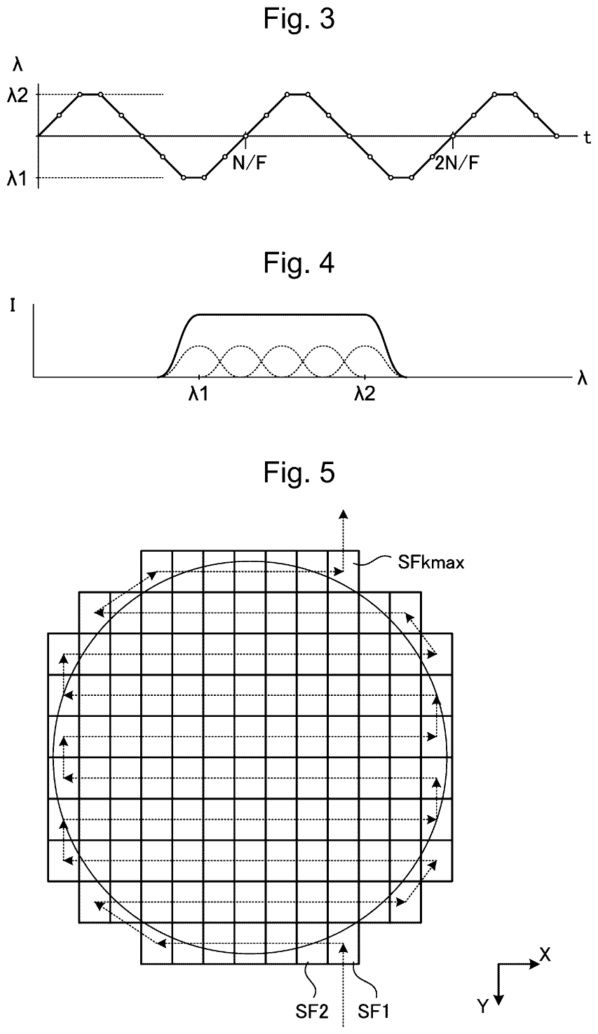

FIG. 3 is a graph illustrating a periodic wavelength change. In FIG. 3, a horizontal axis represents time t and a vertical axis represents a wavelength λ. Each of small circles illustrated in FIG. 3 indicates the time t when the pulse laser beam is output and the center wavelength at that time.

In an example illustrated in FIG. 3, the center wavelength periodically changes between the target short wavelength λ1 and the target long wavelength λ2. A pulse number for one period of the wavelength change is defined as N, and a repetition frequency of the pulse laser beam is defined as F. A period T of the wavelength change is given by an equation below.

T=N/F

FIG. 4 illustrates an integrated spectrum of the pulse laser beam including the center wavelengths. The integrated spectrum illustrated in FIG. 4 corresponds to an integrated spectrum for one period of the wavelength change illustrated in FIG. 3. In FIG. 4, a horizontal axis represents the wavelength k and a vertical axis represents light intensity I. A dashed line represents a spectrum of the pulse laser beam for each pulse, and each center wavelength coincides with a peak wavelength. By changing the center wavelength in multiple stages between the target short wavelength λ1 and the target long wavelength λ2 as illustrated in FIG. 3, the integrated spectrum illustrated in FIG. 4 can have a flat top shape having substantially uniform light intensity I between the target short wavelength λ1 and the target long wavelength λ2.

### 1.5 Scan Exposure

FIG. 5 illustrates a photosensitive substrate exposed by the exposure apparatus 200. The photosensitive substrate is, for example, a single crystal silicon plate having a substantially disk shape. The photosensitive substrate is exposed for each section of scan fields SF1, SF2, and others. Each of the scan fields SF1 and SF2 corresponds to a region where several semiconductor chips of many semiconductor chips formed on the photosensitive substrate are formed, and a mask pattern of one photomask is transferred by scanning of one time. Numbers included in the signs SF1 and SF2 indicate an exposure order. When descriptions are given without specifying the exposure order, the scan field is simply denoted as SF without any number added.

First, the photosensitive substrate is moved such that the first scan field SF1 is irradiated with the pulse laser beam, and the first scan field SF1 is exposed. Next, the photosensitive substrate is moved such that the second scan field SF2 is irradiated with the pulse laser beam, and the second scan field SF2 is exposed. The other scan fields SF are also sequentially exposed, and when a last scan field SFkmax is exposed, exposure of the photosensitive substrate ends.

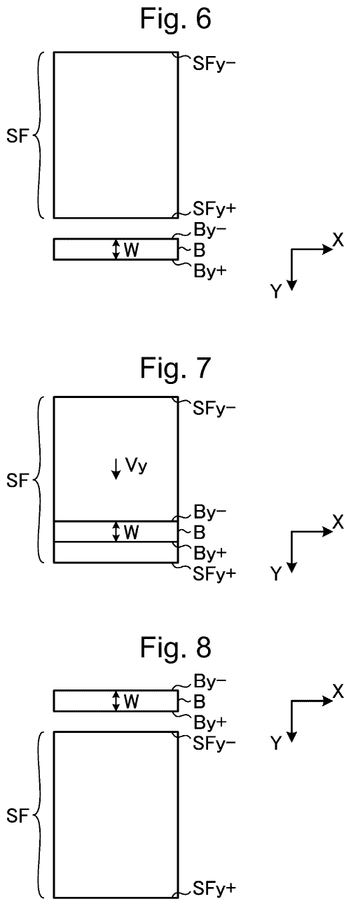

FIG. 6 to FIG. 8 illustrate how a position of the scan field SF of the photosensitive substrate changes with respect to a position of a beam cross section B of the pulse laser beam. A direction in which the position of the scan field SF changes is defined as a Y axis direction, and a direction perpendicular to the Y axis direction is defined as an X axis direction.

When one scan field SF is exposed, the pulse laser beam is continuously output at a predetermined repetition frequency. Continuous output of the pulse laser beam at the predetermined repetition frequency is referred to as burst output. When an exposure position is moved from one scan field SF to another scan field SF, output of the pulse laser beam is stopped. Thus, the burst output is repeated multiple times to expose one photosensitive substrate.

A width in the X axis direction of the scan field SF corresponds to a width in the X axis direction of the beam cross section B of the pulse laser beam at a position of the workpiece table WT (see FIG. 1). A width in the Y axis direction of the scan field SF is larger than a width W in the Y axis direction of the beam cross section B of the pulse laser beam at the position of the workpiece table WT.

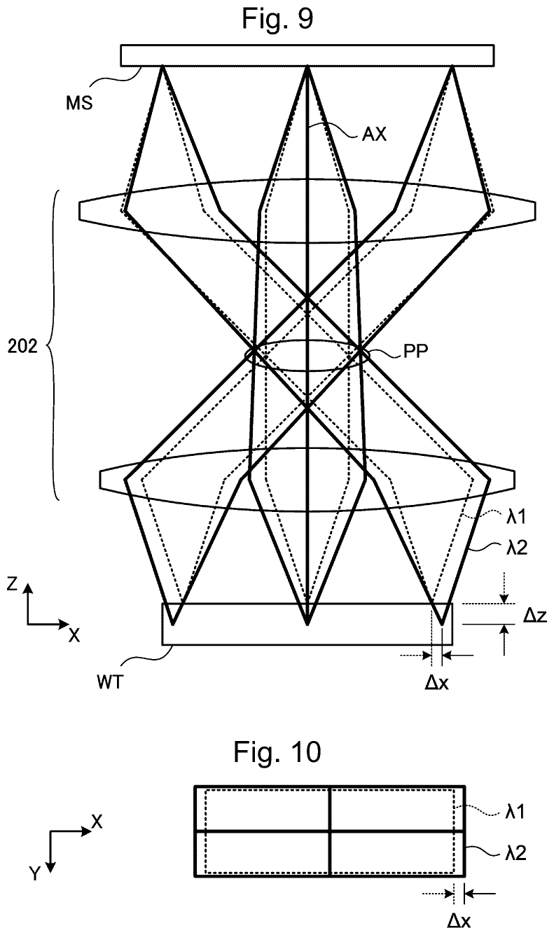

A procedure of scanning and exposing each scan field SF in the Y axis direction to the pulse laser beam is performed in the order of FIG. 6, FIG. 7, and FIG. 8. First, as illustrated in FIG. 6, the workpiece table WT is positioned such that an end SFy+ in a +Y direction of the scan field SF is positioned away from a position of an end By—in a −Y direction of the beam cross section B by a predetermined distance in the −Y direction. Then, the workpiece table WT is accelerated in the +Y direction so as to be a velocity Vy before the end SFy+ in the +Y direction of the scan field SF coincides with the position of the end By—in the −Y direction of the beam cross section B. As illustrated in FIG. 7, the scan field SF is exposed while the workpiece table WT is moved in the +Y direction such that the position of the scan field SF moves uniformly and linearly at the velocity Vy with respect to the position of the beam cross section B. As illustrated in FIG. 8, when the workpiece table WT is moved until the end SFy− in the −Y direction of the scan field SF passes the position of the end By+ in the +Y direction of the beam cross section B, the scanning of the scan field SF ends.

In this way, the exposure is performed while the scan field SF moves with respect to the position of the beam cross section B. When the scan field SF is used as a reference, it can be said that the scanning is performed in the −Y direction with the pulse laser beam.

Required time Ts for the scan field SF to move a distance corresponding to the width W of the beam cross section B of the pulse laser beam at the velocity Vy is as follows.

Ts=W/Vy

An irradiation pulse number Ns of the pulse laser beam with which an arbitrary part of the scan field SF is irradiated is the same as a pulse number of the pulse laser beam generated during the required time Ts, and is as follows.

Ns=F·Ts

The irradiation pulse number Ns of the pulse laser beam with which an arbitrary part of the scan field SF is irradiated is preferably a multiple of the pulse number N for one period of the wavelength change. As a result, any part of the scan field SF is irradiated with the pulse laser beam of the irradiation pulse number Ns having the same integrated spectrum. This makes it possible to manufacture a high-quality electronic device with little variation in an exposure result depending on an irradiation position.

### 1.6 Magnification Distortion

The exposure apparatus 200 transfers a pattern of the photomask to the photosensitive substrate at a prescribed reduction magnification, for example, a size of ¼. However, the size of the pattern transferred to the photosensitive substrate may be larger or smaller than an expected size. This phenomenon can be seen as a deviation of each point in the plane of the photosensitive substrate from its intended position, and this deviation varies depending on a distance from an optical axis, and is therefore referred to as magnification distortion.

In photolithography, depending on design of the exposure apparatus 200 and a setting of the optical system at the time of exposure, whether enlargement or reduction is caused by the magnification distortion is changed, or a degree of enlargement or reduction is changed. In manufacture of an electronic device, exposure is performed multiple times by different exposure apparatuses 200 or different settings, so that the magnification distortion causes the overlay error between multiple layers.

### 1.7 Chromatic Aberration

FIG. 9 is a schematic diagram of the projection optical system 202 included in the exposure apparatus 200. FIG. 9 illustrates marginal light beams of light having the target short wavelength λ1 and the target long wavelength λ2 from the photomask disposed on the mask stage MS to the photosensitive substrate disposed on the workpiece table WT. With respect to the target short wavelength λ1, the position of the photomask is in a conjugate relationship with the position of the photosensitive substrate, and the pattern of the photomask is transferred to the photosensitive substrate.

The optical system of the exposure apparatus 200 is designed so that aberration is minimized at a certain design wavelength, for example, at the target short wavelength λ1. However, in a case where light having a wavelength different from the design wavelength, the target long wavelength λ2 for example, is used, a traveling direction of the light is different from that in a case where the light having the design wavelength is used, due to wavelength dependency of a refraction angle. This difference is called chromatic aberration.

The chromatic aberration has an effect of shifting an image both in a direction of an optical axis AX and in a direction perpendicular to the optical axis AX. A chromatic aberration component that shifts the image in the direction of the optical axis AX is referred to as longitudinal chromatic aberration, and a chromatic aberration component that shifts the image in the direction perpendicular to the optical axis AX is referred to as lateral chromatic aberration. In FIG. 9, the longitudinal chromatic aberration is indicated by Δz, and the lateral chromatic aberration is indicated by Δx.

### 1.8 Magnification Chromatic Aberration

FIG. 10 illustrates how an image formed on the photosensitive substrate is deformed by the projection optical system 202 illustrated in FIG. 9. A dashed line represents an image by the target short wavelength λ1, and a solid line represents an image by the target long wavelength λ2. The lateral chromatic aberration Δx may vary depending on a distance of an object point or an image point from the optical axis AX, and may cause the magnification distortion. The magnification distortion caused by the lateral chromatic aberration Δx is referred to as the magnification chromatic aberration.

When exposure is performed with light including the center wavelengths, since there is a wavelength different from the design wavelength, the magnification chromatic aberration occurs.

### 1.9 Magnification Telecentric Error

When a main light beam is parallel to the optical axis AX on an object side or an image side of an imaging optical system, it is said to be telecentric on the object side or the image side. A projection optical system of a modern exposure apparatus is telecentric on both the object side, i.e. a photomask side, and the image side, i.e. a photosensitive substrate side, and this case is said to be both-side telecentric.

A both-side telecentric optical system has an advantage that, for example, movement of the photosensitive substrate or the photomask in the direction of the optical axis AX does not cause the magnification distortion. In the projection optical system 202 illustrated in FIG. 9, the position of the photomask and the position of the photosensitive substrate are in the conjugate relationship. The projection optical system 202 illustrated in FIG. 9 is both-side telecentric for the light having the wavelength λ1, but may not be both-side telecentric for the light having the wavelength λ2.

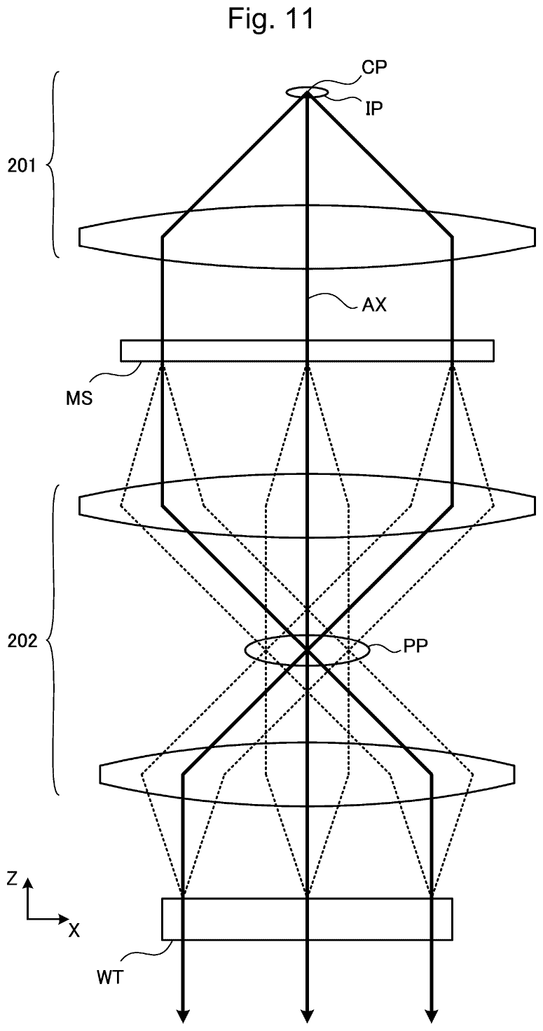

A magnification telecentric error will be described with reference to FIG. 11 to FIG. 19. FIG. 11 is a schematic diagram of an optical system including a part of the illumination optical system 201 and the both-side telecentric projection optical system 202. In FIG. 11, the position of the photomask and the position of the photosensitive substrate are in the conjugate relationship. Furthermore, a pupil IP of the illumination optical system 201 is positioned at a conjugate point CP of a pupil PP of the projection optical system 202. FIG. 11 illustrates an ideal state without a magnification telecentric error. In this case, the size of the image does not change even if the photosensitive substrate moves up and down in the direction of the optical axis AX.

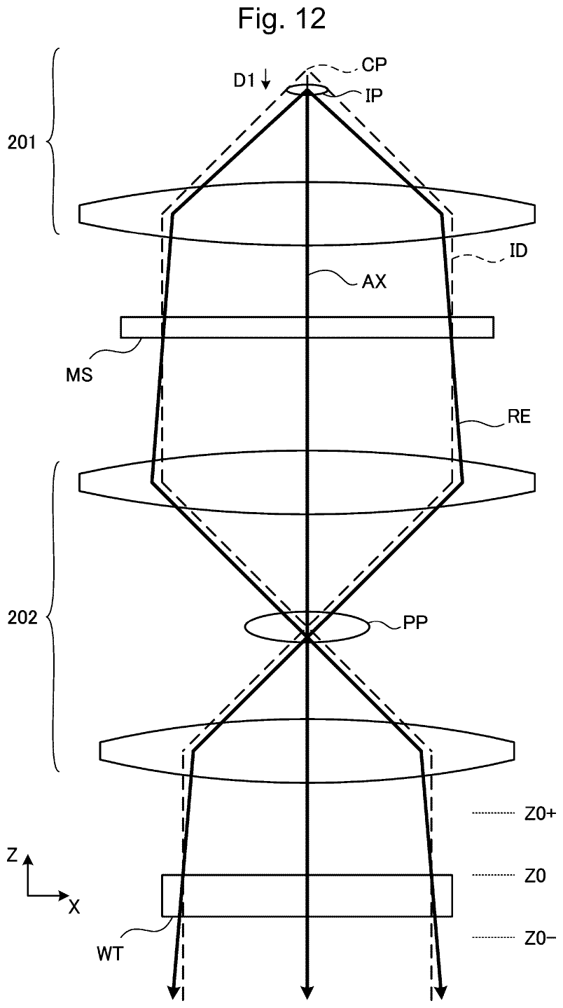

FIG. 12 illustrates a change in the main light beam when the pupil IP of the illumination optical system 201 is shifted in the direction of the optical axis AX in the optical system illustrated in FIG. 11. The pupil IP of the illumination optical system 201 is shifted in a direction of an arrow D1 along the optical axis AX of the pulse laser beam from the conjugate point CP with the pupil PP of the projection optical system 202. As a result, the main light beam changes from an ideal state ID to an actual state RE, and the incident angle with respect to the photosensitive substrate becomes non-perpendicular. At this time, when the photosensitive substrate moves in the direction of the optical axis AX, the size of the image changes. The pupil IP of the illumination optical system 201 corresponds to a first pupil in the present disclosure, the pupil PP of the projection optical system 202 corresponds to a second pupil in the present disclosure, and the position of the conjugate point CP corresponds to a reference position in the present disclosure.

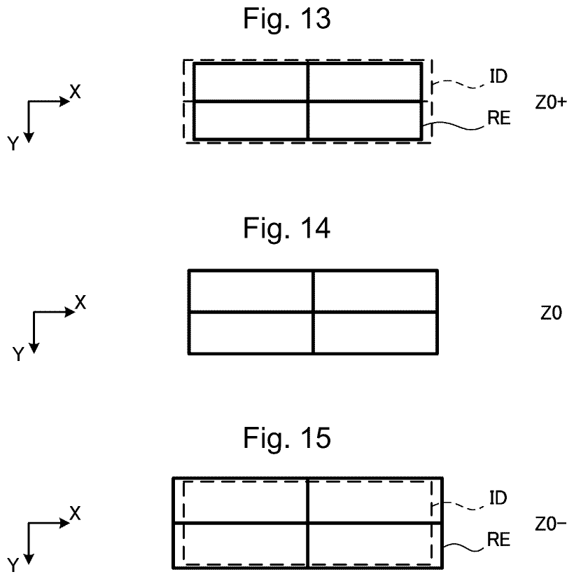

FIG. 13 to FIG. 15 illustrate how an image formed on the photosensitive substrate is changed by the optical system illustrated in FIG. 12. A position Z0 in a Z direction is a best focus position of the projection optical system 202, and at the position Z0, the image formed on the photosensitive substrate does not change before and after the pupil IP is shifted. However, at a position Z0+ deviating from the position Z0 in the Z direction, the image changes from the ideal state ID to the actual state RE and becomes smaller, and conversely, at a position Z0− deviating from Z0 in a −Z direction, the image becomes larger.

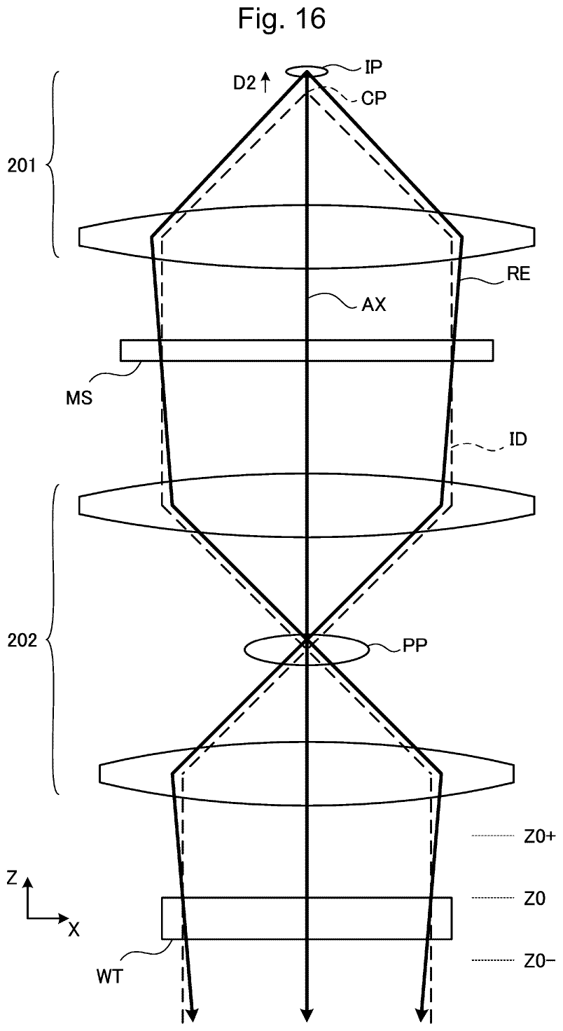

FIG. 16 illustrates a change in the main light beam when the pupil IP of the illumination optical system 201 is shifted in a direction opposite to that in FIG. 12 in the optical system illustrated in FIG. 11. The pupil IP of the illumination optical system 201 is shifted in a direction of an arrow D2 along the optical axis AX of the pulse laser beam from the conjugate point CP with the pupil PP of the projection optical system 202.

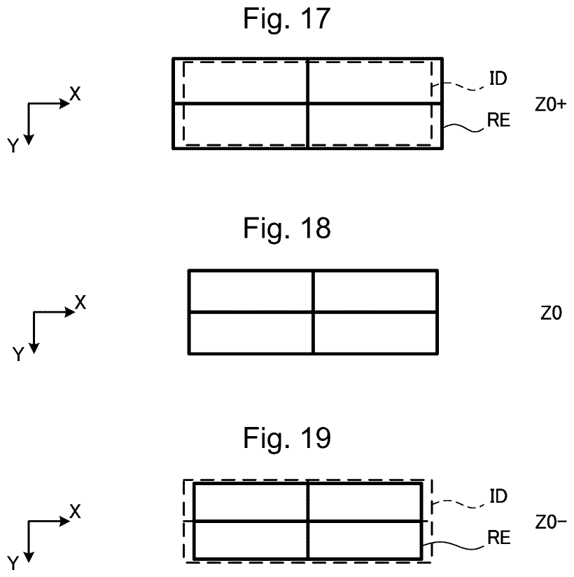

FIG. 17 to FIG. 19 illustrate how an image formed on the photosensitive substrate is changed by the optical system illustrated in FIG. 16. As in FIG. 14, at the position Z0, the image formed on the photosensitive substrate is not deformed before and after the pupil IP is shifted. However, at the position Z0+ deviating from the position Z0 in the Z direction, the image changes from the ideal state ID to the actual state RE and becomes larger, and conversely, at the position Z0− deviating from Z0 in the −Z direction, the image becomes smaller.

As illustrated in FIG. 12 to FIG. 19, an error caused by enlargement or reduction of an image generated when the photosensitive substrate is shifted from the best focus position is referred to as a magnification telecentric error. Since the traveling direction of the main light beam can be controlled by the position of the pupil IP of the illumination optical system 201, the magnitude of the magnification telecentric error can be controlled.

### 1.10 Problem of Comparative Example

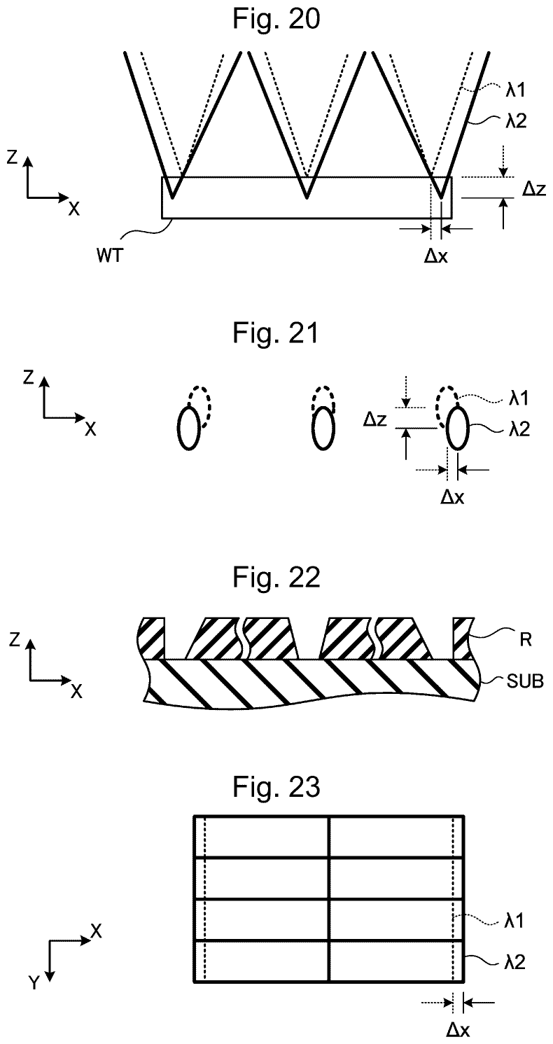

FIG. 20 is a schematic diagram illustrating a part of the marginal light beam of the pulse laser beam incident on the workpiece table WT when the longitudinal chromatic aberration Δz and the lateral chromatic aberration Δx occur. FIG. 20 corresponds to a portion of FIG. 9 extracted. FIG. 20 includes the marginal light beam of the target short wavelength λ1 and the marginal light beam of the target long wavelength λ2, where a tip of each marginal light beam indicates the best focus position of each wavelength.

FIG. 21 schematically illustrates an imaging region of the light of each wavelength of the pulse laser beam illustrated in FIG. 20. The image generated by the pulse laser beam does not suddenly disappear even if it is shifted from the best focus position, but gradually decreases in contrast in an imaging region of a certain size, and is not formed when it is out of the imaging region. The imaging region does not have a distinct boundary, but is conveniently illustrated in an elliptical shape. Due to the longitudinal chromatic aberration Δz, for example, the target long wavelength λ2 forms an image at a position deviating in the −Z direction more than the target short wavelength λ1. On the other hand, the lateral chromatic aberration Δx occurs in opposite directions about the optical axis AX, and for example, the target long wavelength λ2 forms an image at a position deviating outward about the optical axis AX more than the target short wavelength λ1.

FIG. 22 is a sectional view illustrating a resist profile when the photosensitive substrate exposed to the pulse laser beam illustrated in FIG. 20 and FIG. 21 is developed. The photosensitive substrate includes a resist film R formed on a surface of a semiconductor substrate SUB. Since the pulse laser beam illustrated in FIG. 20 and FIG. 21 has the longitudinal chromatic aberration Δz, excellent imaging performance can be obtained over an entire thickness direction of the resist film R even in the resist film R having a large thickness. However, the lateral chromatic aberration Δx occurs in a region away from the optical axis AX of the pulse laser beam, and an imaging position in the X direction differs between the target short wavelength λ1 and the target long wavelength λ2. Therefore, inclination angles of wall surfaces on both sides of a part where the resist film R is removed may be asymmetric.

FIG. 23 illustrates the deviation of the image on the photosensitive substrate scan-exposed to the pulse laser beam illustrated in FIG. 20 and FIG. 21. As illustrated in FIG. 23, the imaging position in the X direction differs between the target short wavelength λ1 and the target long wavelength λ2, and in particular, the deviation becomes remarkable at ends away from the optical axis AX in the X direction and the −X direction. Therefore, even in a case of the resist film R having a small thickness, the image may be shifted or blurred due to the lateral chromatic aberration Δx. In the scan exposure described with reference to FIG. 6 to FIG. 8, the photosensitive substrate is moved in the Y direction while being irradiated with the pulse laser beam, so that the lateral chromatic aberration in the Y direction is averaged.

International Publication No. WO2021/110343 discloses that a pattern is shifted in advance according to a position in a photomask, or an assist pattern (sub-resolution assist feature: SRAF) is inserted. However, such a photomask is optimized for a specific spectral parameter, and other photomasks must be designed and produced if the spectral parameter changes even with the exposure of the same pattern. In addition, there may be no sufficient area to dispose the assist pattern around the pattern to be exposed in the photomask. Further, a dimension of the assist pattern has a lower limit on production, and if the dimension of the assist pattern is too large, an effect of the assist pattern may become excessive.

Embodiments described below relate to suppressing the magnification chromatic aberration by generating a magnification telecentric error −δx to cancel the lateral chromatic aberration Δx when the exposure is performed using multiple wavelengths.

### 2. Exposure System in which Position of Pupil IP of Illumination Optical System 201 is Shifted

### 2.1 Principle

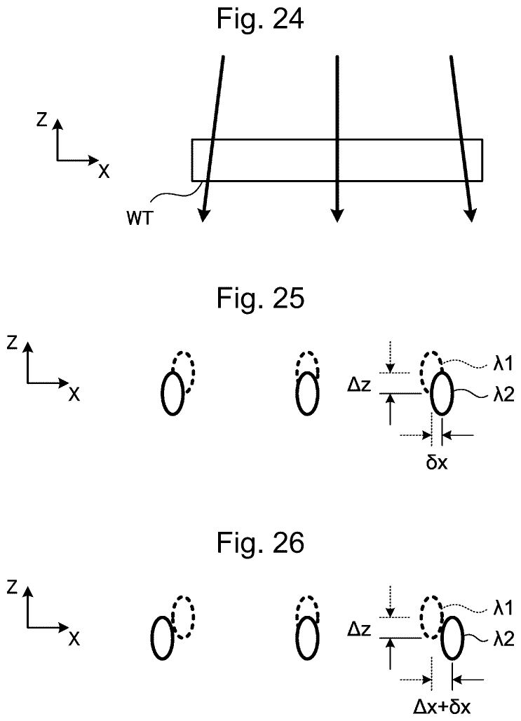

FIG. 24 is a schematic diagram illustrating a part of the main light beam of the pulse laser beam incident on the workpiece table WT when a magnification telecentric error occurs. FIG. 24 corresponds to a portion of FIG. 12 extracted. For convenience of explanation, it is assumed that the lateral chromatic aberration has not occurred or is very small. In this case, the main light beam of the target short wavelength λ1 and the main light beam of the target long wavelength λ2 are common to each other.

FIG. 25 schematically illustrates an imaging region of the light of each wavelength of the pulse laser beam illustrated in FIG. 24. Due to the longitudinal chromatic aberration Δz, for example, the target long wavelength λ2 forms an image at a position deviating in the −Z direction more than the target short wavelength λ1. On the other hand, even when it is assumed that the lateral chromatic aberration has not occurred or is very small, in a case where the incident angle of the main light beam on the photosensitive substrate is non-perpendicular due to the deviation of the pupil IP of the illumination optical system 201, a magnification telecentric error δx determined by the longitudinal chromatic aberration Δz and the incident angle occurs between the target short wavelength λ1 and the target long wavelength λ2.

FIG. 26 schematically illustrates an imaging region of the light of each wavelength when the lateral chromatic aberration Δx is taken into consideration in the pulse laser beam illustrated in FIG. 24. The imaging region illustrated in FIG. 26 corresponds to a sum of the lateral chromatic aberration Δx illustrated in FIG. 21 and the magnification telecentric error δx illustrated in FIG. 25. In FIG. 26, the lateral chromatic aberration Δx and the magnification telecentric error δx act in the same direction to generate large magnification distortion Δx+δx.

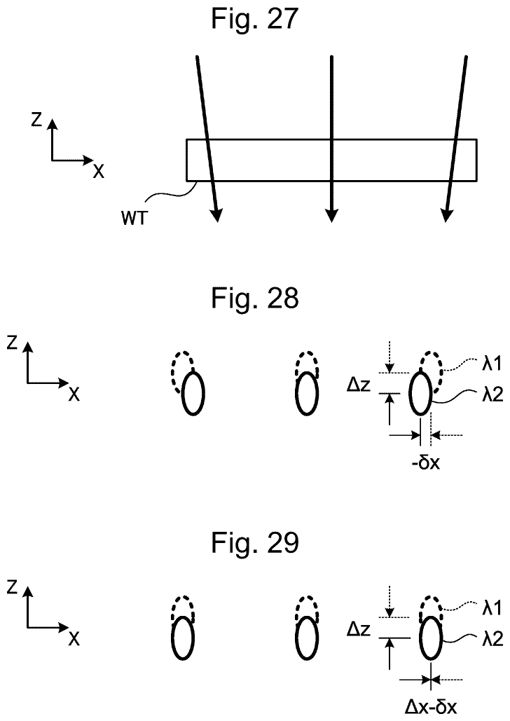

FIG. 27 is a schematic diagram illustrating a part of the main light beam of the pulse laser beam incident on the workpiece table WT when the magnification telecentric error −δx occurs in the direction opposite to that in FIG. 24. FIG. 27 corresponds to a portion of FIG. 16 extracted. When it is assumed that the lateral chromatic aberration has not occurred or is very small for the convenience of explanation, the main light beam of the target short wavelength λ1 and the main light beam of the target long wavelength λ2 are common to each other.

FIG. 28 schematically illustrates an imaging region of the light of each wavelength of the pulse laser beam illustrated in FIG. 27. Due to the longitudinal chromatic aberration Δz, for example, the target long wavelength λ2 forms an image at a position deviating in the −Z direction more than the target short wavelength λ1. On the other hand, even when it is assumed that the lateral chromatic aberration has not occurred or is very small, in the case where the incident angle of the main light beam on the photosensitive substrate is non-perpendicular due to the deviation of the pupil IP of the illumination optical system 201, the magnification telecentric error −δx determined by the longitudinal chromatic aberration Δz and the incident angle occurs between the target short wavelength λ1 and the target long wavelength λ2. Since the direction of the deviation of the pupil IP of the illumination optical system 201 differs between FIG. 25 and FIG. 28, the magnification telecentric error δx in FIG. 25 and the magnification telecentric error −δx in FIG. 28 occur in the opposite directions.

FIG. 29 schematically illustrates an imaging region of the light of each wavelength when the lateral chromatic aberration Δx is taken into consideration in the pulse laser beam illustrated in FIG. 27. The imaging region illustrated in FIG. 29 corresponds to a sum of the lateral chromatic aberration Δx illustrated in FIG. 21 and the magnification telecentric error −δx illustrated in FIG. 28. As illustrated in FIG. 29, the lateral chromatic aberration Δx and the magnification telecentric error −δx are caused to act in the opposite directions to cancel each other, and the deviation of the imaging position due to the lateral chromatic aberration Δx on the photosensitive substrate can be reduced by the magnification telecentric error −δx. Thus, the magnification distortion is reduced.

### 2.2 Configuration

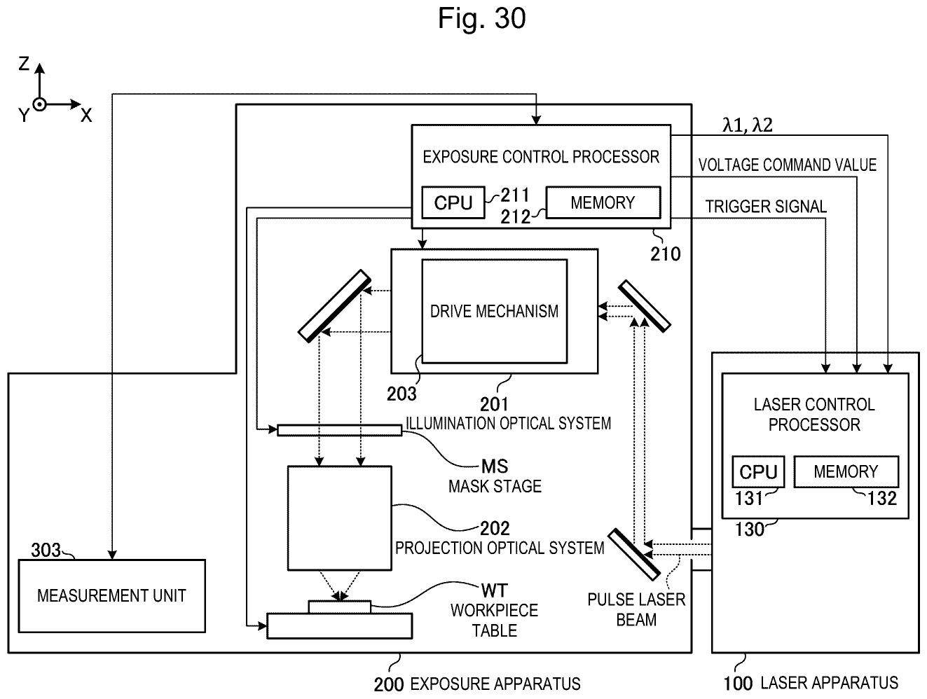

FIG. 30 schematically illustrates a configuration of an exposure system in a first embodiment. In the first embodiment, the exposure apparatus 200 includes a measurement unit 303, and the illumination optical system 201 includes a drive mechanism 203.

The measurement unit 303 includes a stage on which an exposed photosensitive substrate is mounted, and a sensor that observes an exposure state of the photosensitive substrate. The measurement unit 303 drives the stage under control of the exposure control processor 210, measures a pattern formed on the photosensitive substrate by the sensor, and measures magnification distortion from the pattern. The measurement unit 303 corresponds to a measurement sensor in the present disclosure.

The drive mechanism 203 includes an actuator that drives at least one optical element included in the illumination optical system 201 in order to adjust the position of the pupil IP of the illumination optical system 201. As described with reference to FIG. 12 and FIG. 16, the drive mechanism 203 is configured to adjust the position of the pupil IP of the illumination optical system 201, along the optical axis AX of the pulse laser beam, both in the direction of the arrow D1 approaching the pupil PP from the conjugate point CP with the pupil PP of the projection optical system 202 and in the direction of the arrow D2 away from the pupil PP. The drive mechanism 203 operates under the control of the exposure control processor 210.

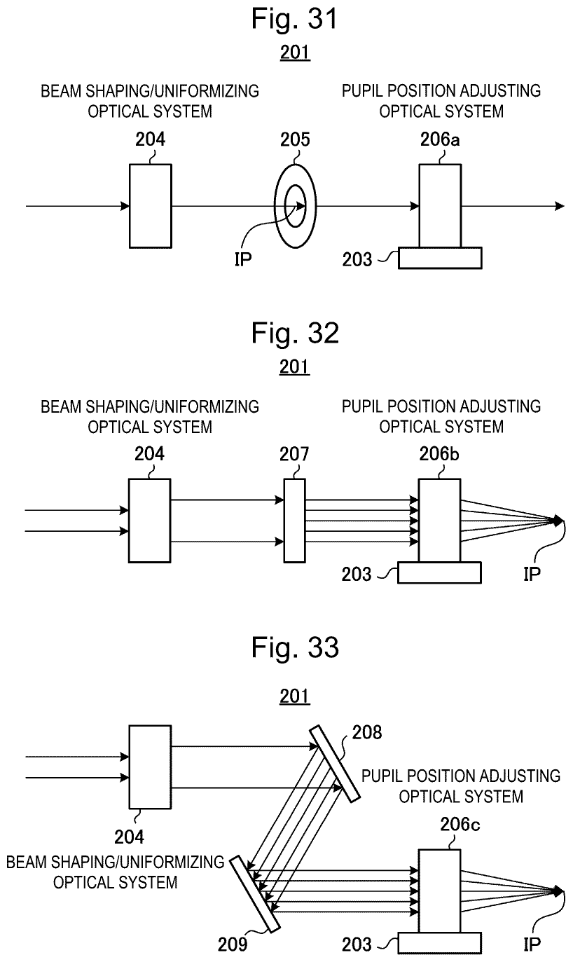

FIG. 31 conceptually illustrates a first example of the illumination optical system 201 capable of moving the position of the pupil IP. The illumination optical system 201 includes a beam shaping/uniformizing optical system 204, a mechanical aperture 205, and a pupil position adjusting optical system 206a.

The beam shaping/uniformizing optical system 204 shapes and uniformizes a pulse laser beam having a substantially rectangular beam cross section and a Gaussian light intensity distribution into a desired beam cross section and a uniform light intensity distribution, for example.

The mechanical aperture 205 is a mechanical diaphragm and is disposed near the pupil IP. The mechanical aperture 205 corresponds to a mechanical diaphragm in the present disclosure.

The pupil position adjusting optical system 206a irradiates the photomask with the light outcoming from the pupil IP. By moving at least one of optical elements included in the pupil position adjusting optical system 206a by the drive mechanism 203, the position of the pupil IP is moved in the direction of the optical axis AX.

FIG. 32 conceptually illustrates a second example of the illumination optical system 201 capable of moving the position of the pupil IP. The illumination optical system 201 includes the beam shaping/uniformizing optical system 204, a diffractive optical element 207, and a pupil position adjusting optical system 206b.

The diffractive optical element 207 is an optical element that has a large number of recesses and projections on its surface and branches the transmitted light into a plurality of diffracted light beams. The recesses and the projections on the surface of the diffractive optical element 207 are designed to direct the diffracted light beams in respective desired directions. The diffracted light beams outcoming from the diffractive optical element 207 enter the pupil position adjusting optical system 206b.

The pupil position adjusting optical system 206b condenses the diffracted light beams on the pupil IP. By moving at least one of the optical elements included in the pupil position adjusting optical system 206b by the drive mechanism 203, a light condensing position, that is, the position of the pupil IP is moved in the direction of the optical axis AX.

FIG. 33 conceptually illustrates a third example of the illumination optical system 201 capable of moving the position of the pupil IP. The illumination optical system 201 includes the beam shaping/uniformizing optical system 204, a micromirror array 208, a mirror 209, and a pupil position adjusting optical system 206c.

The micromirror array 208 is an optical element that includes a plurality of mirrors with respectively adjustable inclination and branches the light incident on the micromirror array 208 into a plurality of reflected light beams. The inclination of the mirrors included in the micromirror array 208 is adjusted so as to direct the reflected light beams in the respective desired directions. The reflected light beams outcoming from the micromirror array 208 enter the pupil position adjusting optical system 206c via the mirror 209.

The pupil position adjusting optical system 206c condenses the reflected light beams on the pupil IP. By moving at least one of the optical elements included in the pupil position adjusting optical system 206c by the drive mechanism 203, the light condensing position, that is, the position of the pupil IP is moved in the direction of the optical axis AX.

### 2.3 Operation (Correction of Magnification Distortion)

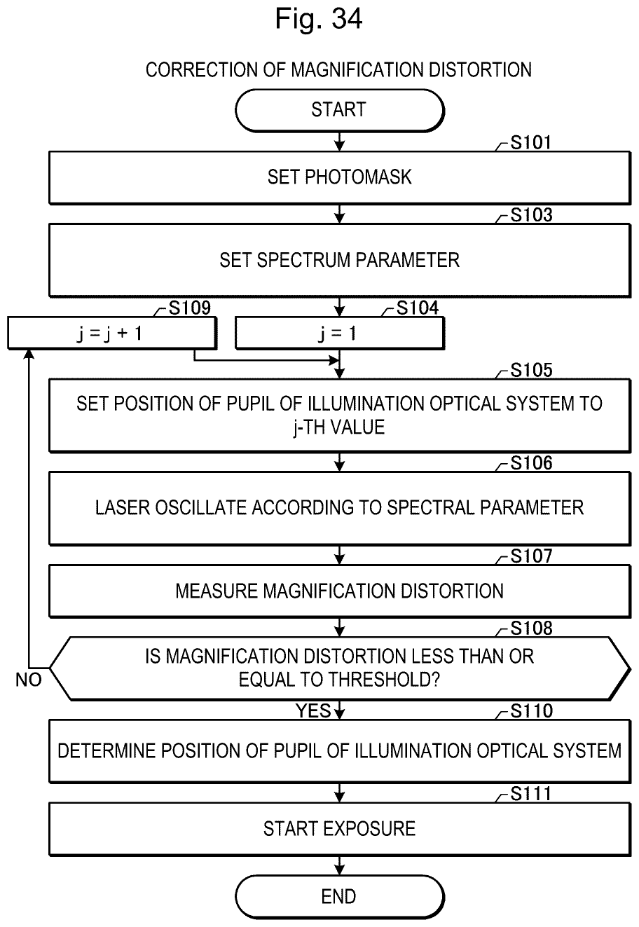

FIG. 34 is a flowchart illustrating processing of correcting the magnification distortion in the first embodiment. The exposure control processor 210 corrects the magnification distortion by controlling the drive mechanism 203 so as to reduce the deviation of the imaging position due to the lateral chromatic aberration Δx as follows based on the magnification distortion measured by the measurement unit 303.

In S101, the exposure control processor 210 controls an unillustrated conveyance device so as to set the photomask on the mask stage MS of the exposure apparatus 200.

In S103, the exposure control processor 210 sets a spectral parameter of the pulse laser beam including the center wavelengths. The spectral parameter includes, for example, the target short wavelength λ1 and the target long wavelength λ2. Alternatively, the spectral parameter may include the wavelength difference between the target short wavelength λ1 and the target long wavelength λ2. The spectral parameter may further include a pulse number N for one period of the wavelength change.

In S104, the exposure control processor 210 sets a value of a counter j that specifies the position of the pupil IP of the illumination optical system 201 to an initial value of 1.

In S105, the exposure control processor 210 controls the drive mechanism 203 so that the position of the pupil IP of the illumination optical system 201 becomes a j-th value.

In S106, the exposure control processor 210 transmits various kinds of parameters and signals to the laser control processor 130 so as to laser oscillate according to the spectral parameter set in S103. Further, the exposure control processor 210 controls the mask stage MS and the workpiece table WT so that an image of the photomask by the pulse laser beam including the center wavelengths is transferred onto the photosensitive substrate and the photosensitive substrate is exposed. Here, the photosensitive substrate to be exposed may be a photosensitive substrate for measurement, which is different from a photosensitive substrate for manufacturing a semiconductor device.

In S107, the exposure control processor 210 controls the measurement unit 303 to measure the magnification distortion from the pattern formed on the exposed photosensitive substrate.

In S108, the exposure control processor 210 determines whether or not the magnification distortion is less than or equal to a threshold. If the magnification distortion exceeds the threshold (S108: NO), the exposure control processor 210 advances the processing to S109. If the magnification distortion is less than or equal to the threshold (S108: YES), the exposure control processor 210 advances the processing to S110.

In S109, the exposure control processor 210 adds 1 to the value of the counter j to update j, and then returns the processing to S105. An upper limit value may be set for the value of the counter j, and the exposure control processor 210 may end the processing of the present flowchart when j reaches the upper limit value.

In S110, the exposure control processor 210 determines the position of the pupil IP of the illumination optical system 201 to be the j-th value at which the magnification distortion becomes less than or equal to the threshold.

In S111, the exposure control processor 210 disposes the photosensitive substrate for manufacturing a semiconductor device on the workpiece table WT, starts the exposure, and ends the processing of the present flowchart.

### 2.4 Effect

According to the first embodiment, the exposure system includes the illumination optical system 201 configured to illuminate the photomask with the pulse laser beam including the target short wavelength λ1 and the target long wavelength λ2, and the projection optical system 202 configured to illuminate the photosensitive substrate with the pulse laser beam that has passed through the photomask and to project an image of the photomask. The position of the pupil IP of the illumination optical system 201 is shifted from the conjugate point CP of the pupil PP of the projection optical system 202 in the direction of the arrow D2 for reducing, by the magnification telecentric error −δx, the deviation of the imaging position due to the lateral chromatic aberration Δx on the photosensitive substrate.

Accordingly, since the position of the pupil IP of the illumination optical system 201 is shifted, the deviation of the imaging position due to the lateral chromatic aberration Δx can be reduced by the magnification telecentric error −δx, so that even a thick resist film can be accurately processed. In addition, a degree of freedom in the design of the photomask is higher than in a case where the deviation of the imaging position is reduced by the design of the photomask. Further, when the wavelength difference between the target short wavelength λ1 and the target long wavelength λ2 is changed, it is not necessary to redesign the photomask separately according to the wavelength difference, and a common photomask can be used.

According to the first embodiment, the position of the pupil IP is shifted from the conjugate point CP of the pupil PP along the optical axis AX of the pulse laser beam.

Accordingly, by shifting the pupil IP in the direction of the optical axis AX, the magnification telecentric error −δx can be generated while suppressing a change in the optical axis AX of the pulse laser beam incident on the photosensitive substrate.

According to the first embodiment, the exposure system includes the drive mechanism 203 configured to adjust the position of the pupil IP, and the exposure control processor 210 configured to control the drive mechanism 203 so as to reduce the deviation of the imaging position due to the lateral chromatic aberration Δx.

Accordingly, since the position of the pupil IP can be adjusted by the drive mechanism 203, the magnification distortion can be suppressed even when the spectral parameter such as the wavelength difference between the target short wavelength λ1 and the target long wavelength λ2 is changed.

According to the first embodiment, the drive mechanism 203 is configured to adjust the position of the pupil IP, along the optical axis AX of the pulse laser beam, both in the direction of the arrow D1 approaching the pupil PP from the conjugate point CP of the pupil PP and in the direction of the arrow D2 away from the pupil PP.

Accordingly, it is possible to select an appropriate moving direction even when the moving direction of the pupil IP for suppressing the magnification distortion is the direction of the arrow D1 approaching the pupil PP or is the direction of the arrow D2 away from the pupil PP.

According to the first embodiment, the exposure system includes the measurement unit 303 configured to measure the pattern formed by projection onto the photosensitive substrate, and the exposure control processor 210 controls the drive mechanism 203 based on a measurement result of the measurement unit 303.

Accordingly, the magnification distortion can be accurately suppressed based on the measurement result of the measurement unit 303.

According to the first embodiment, the measurement unit 303 measures the magnification distortion of the pattern formed by the projection onto the photosensitive substrate, and the exposure control processor 210 controls the drive mechanism 203 based on the magnification distortion.

Accordingly, the position of the pupil IP can be adjusted so as to reduce the magnification distortion.

In other respects, the first embodiment is similar to the comparative example.

### 3. Exposure System that Determines Position of Pupil IP of Illumination Optical System 201 Based on Spectral Parameter

### 3.1 Configuration

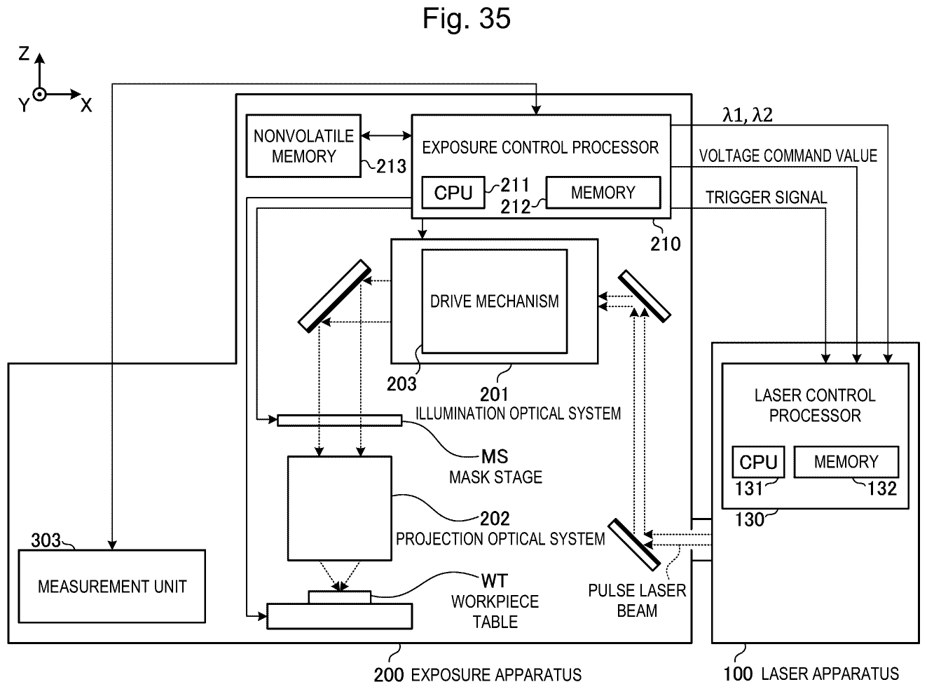

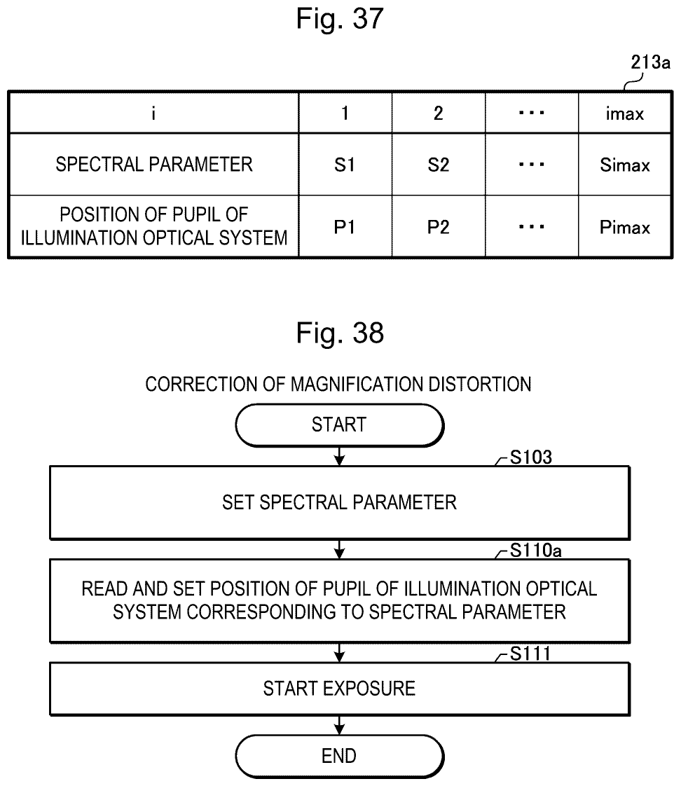

FIG. 35 schematically illustrates a configuration of an exposure system in a second embodiment. In the second embodiment, the exposure apparatus 200 includes a nonvolatile memory 213. The nonvolatile memory 213 stores a correction table 213a (see FIG. 37) in which the spectral parameter is associated with the position of the pupil IP of the illumination optical system 201. The nonvolatile memory 213 is accessible to the exposure control processor 210.

### 3.2 Operation

### 3.2.1 Creation of Correction Table

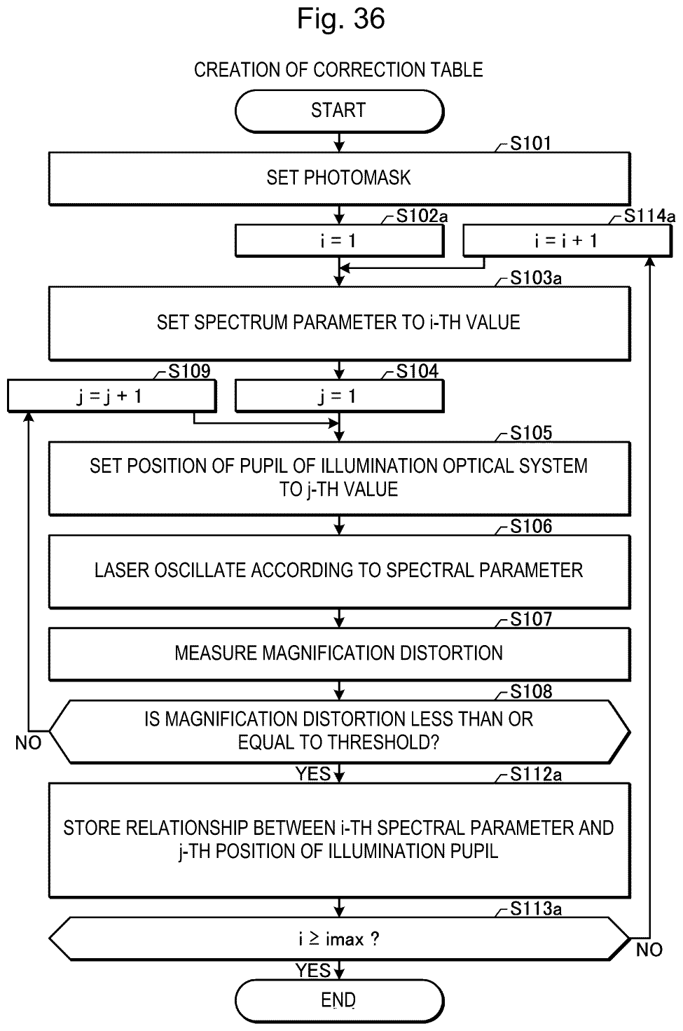

FIG. 36 is a flowchart illustrating processing of creating the correction table 213a in the second embodiment. The exposure control processor 210 creates the correction table 213a as follows.

In S101, the exposure control processor 210 controls an unillustrated conveyance device so as to set the photomask on the mask stage MS of the exposure apparatus 200. This is the same as the processing included in the correction of the magnification distortion of the first embodiment.

In S102a, the exposure control processor 210 sets a value of a counter i that specifies the spectral parameter to an initial value of 1.

In S103a, the exposure control processor 210 sets the spectral parameter to an i-th value.

The processing from S104 to S109 is the same as the processing included in the correction of the magnification distortion of the first embodiment, and the exposure control processor 210 searches for the position of the pupil IP at which the magnification distortion is less than or equal to the threshold for the given spectral parameter. If the magnification distortion is less than or equal to the threshold (S108: YES), the exposure control processor 210 advances the processing to S112a.

In S112a, the exposure control processor 210 causes a correspondence relationship between an i-th spectral parameter and a j-th position of the pupil IP of the illumination optical system 201 at which the magnification distortion is less than or equal to the threshold to be stored in the correction table 213a of the nonvolatile memory 213, based on the measurement result of the magnification distortion by the measurement unit 303.

In S113a, the exposure control processor 210 determines whether or not the value of the counter i has reached a maximum value imax. When the value of the counter i has reached the maximum value imax (S113a: YES), the exposure control processor 210 ends the processing of the present flowchart. When the value of the counter i is smaller than the maximum value imax (S113a: NO), the exposure control processor 210 advances the processing to S114a.

In S114a, the exposure control processor 210 adds 1 to the value of the counter i to update i, and then returns the processing to S103a.

FIG. 37 illustrates an example of the correction table 213a stored in the nonvolatile memory 213. The correction table 213a is a data table storing spectral parameters S1 to Simax and positions P1 to Pimax of the pupil IP of the illumination optical system 201 at which the magnification distortion is less than or equal to the threshold, corresponding to the values 1 to imax of the counter i. The positions P1 to Pimax of the pupil IP correspond to a control parameter in the present disclosure. A different correction table 213a may be created for each photomask.

### 3.2.2 Correction of Magnification Distortion

FIG. 38 is a flowchart illustrating processing of correcting the magnification distortion in the second embodiment. The exposure control processor 210 controls the drive mechanism 203 based on the spectral parameter of the pulse laser beam as follows. It is assumed that the photomask is already set on the mask stage MS.

In S103, the exposure control processor 210 sets the spectral parameter of the pulse laser beam. This is the same as the first embodiment.

In S110a, the exposure control processor 210 sets the position of the pupil IP of the illumination optical system 201 corresponding to the set spectral parameter to the value read from the correction table 213a, and controls the drive mechanism 203.

In S111, the exposure control processor 210 disposes the photosensitive substrate on the workpiece table WT, starts the exposure, and ends the processing of the present flowchart.

In other respects, the second embodiment is similar to the first embodiment.

### 3.3 Effect

According to the second embodiment, the exposure control processor 210 can access the correction table 213a in which the wavelength difference between the target short wavelength λ1 and the target long wavelength λ2 is associated with the positions P1 to Pimax of the pupil IP, and reads the position of the pupil IP corresponding to the wavelength difference from the correction table 213a to control the drive mechanism 203.

Accordingly, since the position of the pupil IP can be read from the correction table 213a based on the wavelength difference between the target short wavelength λ1 and the target long wavelength λ2, the drive mechanism 203 can be quickly controlled.

According to the second embodiment, the exposure control processor 210 controls the drive mechanism 203 based on the spectral parameter of the pulse laser beam. For example, the drive mechanism 203 may be controlled not only using the correction table 213a but also using a function of the spectral parameter and the control parameter for the drive mechanism 203. Accordingly, since the control is performed based on the spectral parameter, a process for controlling the drive mechanism 203 can be simplified.

According to the second embodiment, the exposure control processor 210 can access the correction table 213a in which the spectral parameters S1 to Simax and the positions P1 to Pimax of the pupil IP are associated with each other, and reads the position of the pupil IP corresponding to the spectral parameter from the correction table 213a to control the drive mechanism 203.

Accordingly, since the position of the pupil IP can be read from the correction table 213a based on the spectral parameters S1 to Simax, the drive mechanism 203 can be quickly controlled.

According to the second embodiment, the exposure system includes the measurement unit 303 configured to measure the pattern formed by the projection onto the photosensitive substrate, and the exposure control processor 210 causes the correspondence relationship between the spectral parameters S1 to Simax and the positions P1 to Pimax of the pupil IP to be stored in the correction table 213a, based on the measurement result of the measurement unit 303.

Accordingly, it is possible to create a highly reliable correction table 213a for adjusting the position of the pupil IP based on the measurement result.

According to the second embodiment, the measurement unit 303 measures the magnification distortion of the pattern formed by the projection onto the photosensitive substrate, and the exposure control processor 210 causes, for each of the spectral parameters S1 to Simax, the correspondence relationship with the positions P1 to Pimax of the pupil IP at which the magnification distortion becomes less than or equal to the threshold to be stored in the correction table 213a.

Accordingly, it is possible to create a highly reliable correction table 213a for reducing the magnification distortion based on the measurement result of the magnification distortion.

### 4. Exposure System Including Measurement Unit 303b Separate from Exposure Apparatus 200

### 4.1 Configuration

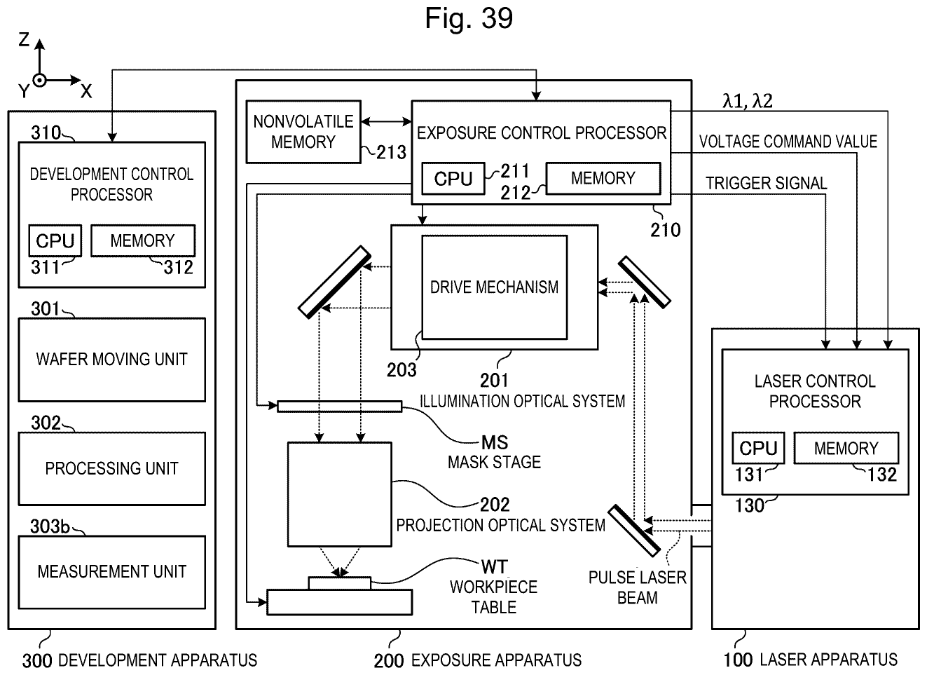

FIG. 39 schematically illustrates a configuration of an exposure system according to a third embodiment. In the third embodiment, the exposure system includes a development apparatus 300 separate from the exposure apparatus 200. The development apparatus 300 includes a wafer moving unit 301, a processing unit 302, a measurement unit 303b, and a development control processor 310.

The wafer moving unit 301 is a device that transfers the photosensitive substrate to and from the exposure apparatus 200 and moves the photosensitive substrate inside the development apparatus 300.

The processing unit 302 is a device that performs application of a resist film on the photosensitive substrate, post-exposure baking (PEB) of the photosensitive substrate exposed in the exposure apparatus 200, supplying of a developer, cleaning, drying, post-development baking (PDB), and the like.

The measurement unit 303b is a device that measures the pattern formed on the photosensitive substrate by exposure and development. The measurement unit 303b may be a cross-sectional inspection SEM that measures a resist profile, a pattern position measurement device that measures the overlay error, or a device that measures the magnification distortion from a planar shape of the resist film. The measurement unit 303b corresponds to the measurement sensor in the present disclosure. The measurement unit 303b may be provided separately from the development apparatus 300.

The development control processor 310 is a processing device including a memory 312 in which a control program is stored and a CPU 311 which executes the control program. The development control processor 310 is specially configured or programmed to execute various kinds of processing included in the present disclosure.

The exposure apparatus 200 may not include the measurement unit 303 described in the first embodiment.

### 4.2 Operation (Correction of Magnification Distortion)

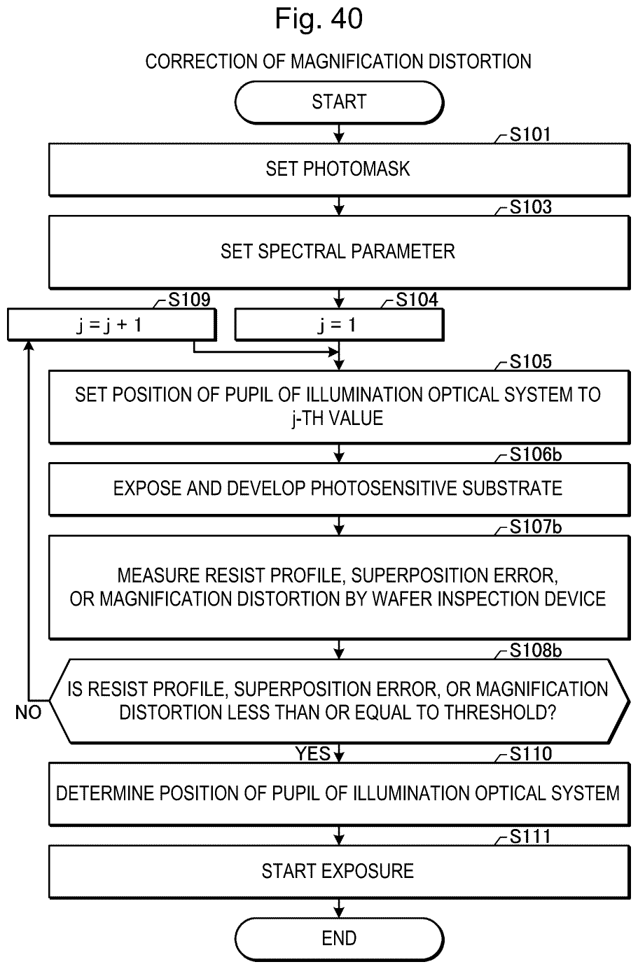

FIG. 40 is a flowchart illustrating processing of correcting the magnification distortion in the third embodiment. As described below, the development control processor 310 develops and measures the photosensitive substrate, the exposure control processor 210 controls the drive mechanism 203 so as to reduce the deviation of the imaging position due to the lateral chromatic aberration Δx based on the measurement result, and thus the magnification distortion is corrected.

Processing of S101 to S105 is the same as that of the first embodiment. In S106b, not only the exposure control processor 210 controls the exposure apparatus 200 to expose the photosensitive substrate, but also the development control processor 310 controls the development apparatus 300 so that the exposed photosensitive substrate is developed by the development apparatus 300.

In S107b, the development control processor 310 controls the measurement unit 303b to measure the resist profile, the overlay error, or the magnification distortion of the exposed and developed photosensitive substrate. The resist profile is measured as a larger value as the inclination angles of the wall surfaces of the resist film are asymmetric, for example.

In S108b, the exposure control processor 210 receives the measurement result of the resist profile, the overlay error, or the magnification distortion measured by the measurement unit 303b from the development control processor 310, and determines whether or not the measurement result is less than or equal to a threshold. If the measurement result exceeds the threshold (S108b: NO), the exposure control processor 210 advances the processing to S109. If the measurement result is less than or equal to the threshold (S108b: YES), the exposure control processor 210 advances the processing to S110. The processing of S109, S110 and S111 is the same as that of the first embodiment.

In other respects, the third embodiment is similar to the first embodiment. Alternatively, in a configuration in which the exposure apparatus 200 includes the nonvolatile memory 213 as in the second embodiment, the exposure system may include the measurement unit 303b separate from the exposure apparatus 200.

### 4.3 Effect

According to the third embodiment, the exposure system includes the measurement unit 303b configured to measure the pattern formed by the projection and development on the photosensitive substrate, and the exposure control processor 210 controls the drive mechanism 203 based on the measurement result of the measurement unit 303b.

Accordingly, product quality can be further improved by measuring the developed pattern and controlling the drive mechanism 203 based on the measurement result.

According to the third embodiment, the measurement unit 303b measures the resist profile of the photosensitive substrate, and the exposure control processor 210 controls the drive mechanism 203 based on the asymmetry of the resist profile.

Accordingly, since the drive mechanism 203 is controlled based on the asymmetry of the resist profile of the developed photosensitive substrate, it is possible to manufacture a product with reduced asymmetry of the resist profile.

According to the third embodiment, the measurement unit 303b measures the overlay error between multiple layers formed by multiple instances of the projection and the development, and the exposure control processor 210 controls the drive mechanism 203 based on the overlay error.

Accordingly, since the drive mechanism 203 is controlled based on the overlay error of the developed photosensitive substrate, it is possible to manufacture a product having a small overlay error.

According to the third embodiment, the measurement unit 303b measures the magnification distortion from the planar shape of the resist film included in the photosensitive substrate, and the exposure control processor 210 controls the drive mechanism 203 based on the magnification distortion.

Accordingly, since the drive mechanism 203 is controlled based on the magnification distortion measured from the planar shape of the resist film of the developed photosensitive substrate, it is possible to manufacture a product having small magnification distortion.

### 5. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An exposure system comprising:
an illumination optical system configured to illuminate a photomask with a pulse laser beam including a plurality of center wavelengths; and
a projection optical system configured to illuminate a photosensitive substrate with the pulse laser beam that has passed through the photomask and to project an image of the photomask,
a position of a first pupil that is a pupil of the illumination optical system being shifted from a reference position in a conjugate relationship with a second pupil that is a pupil of the projection optical system in a direction of reducing, by a magnification telecentric error, deviation of an imaging position due to lateral chromatic aberration on the photosensitive substrate.

2. The exposure system according to claim 1, wherein
the position of the first pupil is shifted from the reference position along an optical axis of the pulse laser beam.

3. The exposure system according to claim 1, further comprising:
a drive mechanism configured to adjust the position of the first pupil; and
a processor configured to control the drive mechanism to reduce the deviation.

4. The exposure system according to claim 3, wherein
the drive mechanism is configured to be capable of adjusting the position of the first pupil, along an optical axis of the pulse laser beam, both in a direction approaching the second pupil from the reference position and in a direction away from the second pupil.

5. The exposure system according to claim 3, wherein
the illumination optical system includes a mechanical diaphragm disposed near the first pupil, and a pupil position adjusting optical system driven by the drive mechanism.

6. The exposure system according to claim 3, wherein
the illumination optical system includes a diffractive optical element, and a pupil position adjusting optical system configured to condense the pulse laser beam that has passed through the diffractive optical element.

7. The exposure system according to claim 3, wherein
the illumination optical system includes a micromirror array, and a pupil position adjusting optical system configured to condense the pulse laser beam reflected by the micromirror array.

8. The exposure system according to claim 3, further comprising
a measurement sensor configured to measure a pattern formed by projection onto the photosensitive substrate, wherein
the processor controls the drive mechanism based on a measurement result of the measurement sensor.

9. The exposure system according to claim 8, wherein
the measurement sensor measures magnification distortion of the pattern formed by the projection onto the photosensitive substrate, and
the processor controls the drive mechanism based on the magnification distortion.

10. The exposure system according to claim 3, wherein
the center wavelengths include a first wavelength and a second wavelength, and
the processor is capable of accessing a data table in which a wavelength difference between the first wavelength and the second wavelength and a control parameter for the drive mechanism are associated with each other, and reads the control parameter corresponding to the wavelength difference from the data table to control the drive mechanism.

11. The exposure system according to claim 3, wherein
the processor controls the drive mechanism based on a spectral parameter of the pulse laser beam.

12. The exposure system according to claim 11, wherein
the processor is capable of accessing a data table in which the spectral parameter and a control parameter for the drive mechanism are associated with each other, and reads the control parameter corresponding to the spectral parameter from the data table to control the drive mechanism.

13. The exposure system according to claim 12, further comprising
a measurement sensor configured to measure a pattern formed by projection onto the photosensitive substrate, wherein
the processor causes a correspondence relationship between the spectral parameter and the control parameter to be stored in the data table, based on a measurement result of the measurement sensor.

14. The exposure system according to claim 13, wherein
the measurement sensor measures magnification distortion of the pattern formed by the projection onto the photosensitive substrate, and
the processor causes, for each of a plurality of values of the spectral parameter, the correspondence relationship with the control parameter with which the magnification distortion becomes less than or equal to a threshold to be stored in the data table.

15. The exposure system according to claim 13, wherein
the measurement sensor measures the pattern formed by projection and development on the photosensitive substrate.

16. The exposure system according to claim 3, further comprising
a measurement sensor configured to measure a pattern formed by projection and development on the photosensitive substrate, wherein
the processor controls the drive mechanism based on a measurement result of the measurement sensor.

17. The exposure system according to claim 16, wherein
the measurement sensor measures a resist profile of the photosensitive substrate, and
the processor controls the drive mechanism based on asymmetry of the resist profile.

18. The exposure system according to claim 16, wherein
the measurement sensor measures an overlay error between multiple layers formed by multiple instances of the projection and the development, and the processor controls the drive mechanism based on the overlay error.

19. The exposure system according to claim 16, wherein
the measurement sensor measures magnification distortion from a planar shape of a resist film included in the photosensitive substrate, and
the processor controls the drive mechanism based on the magnification distortion.

20. A method of manufacturing an electronic device, comprising
exposing, with an exposure system, a photosensitive substrate to a pulse laser beam to manufacture the electronic device,
the exposure system including
an illumination optical system configured to illuminate a photomask with the pulse laser beam including a plurality of center wavelengths, and
a projection optical system configured to illuminate the photosensitive substrate with the pulse laser beam that has passed through the photomask and to project an image of the photomask,
a position of a first pupil that is a pupil of the illumination optical system being shifted from a reference position in a conjugate relationship with a second pupil that is a pupil of the projection optical system in a direction of reducing, by a magnification telecentric error, deviation of an imaging position due to lateral chromatic aberration on the photosensitive substrate.
